(19) United States
(12) Patent Application Publication
(10) Pub. No.: US 2025/0255169 A1
(43) Pub. Date: Aug. 7, 2025

(54) METHOD OF MANUFACTURING DISPLAY DEVICE AND ELECTRONIC DEVICE INCLUDING DISPLAY DEVICE MANUFACTURED USING THE METHOD

(71) Applicant: Samsung Display Co., LTD., Yongin-si (KR)

(72) Inventors: KWANGMIN LEE, Yongin-si (KR); JIHOON KIM, Yongin-si (KR); SUNG-DONG PARK, Yongin-si (KR); YOUNGBOK PARK, Yongin-si (KR); SANGMOO LEE, Yongin-si (KR)

(21) Appl. No.: 19/033,797

(22) Filed: Jan. 22, 2025

(30) Foreign Application Priority Data
Feb. 6, 2024 (KR) 10-2024-0018112
Apr. 12, 2024 (KR) 10-2024-0049178

(51) Int. Cl. H10K 71/00; H10K 59/80; H10K 59/88

(52) U.S. Cl. CPC H10K 71/851; H10K 59/8793; H10K 59/88

(57) ABSTRACT

A method of manufacturing a display device includes forming a display panel on a first surface of a mother substrate including a cell area and a dummy area surrounding the cell area, the display panel overlapping the cell area; attaching a protection film overlapping the display panel to the first surface of the mother substrate; forming a first cutting line along an edge of the cell area on the mother substrate; forming a second cutting line overlapping the dummy area and having a length greater than the first cutting line in a thickness direction of the mother substrate on the mother substrate; reducing a thickness of the mother substrate by spraying an etchant toward a second surface opposite to the first surface of the mother substrate; and removing the dummy area of the mother substrate by spraying the etchant toward the second surface of the mother substrate.

### CROSS-REFERENCE TO RELATED APPLICATION

The present application claims priority to and the benefit of Korean Patent Application No. 10-2024-0018112, filed on Feb. 6, 2024, and Korean Patent Application No. 10-2024-0049178, filed on Apr. 12, 2024, in the Korean Intellectual Property Office, the disclosures of which are herein incorporated by reference in their entireties.

### BACKGROUND

### 1. Field

Aspects of the present disclosure relate generally to a method of manufacturing a display device and an electronic device including a display device manufactured using the method.

### 2. Description of the Related Art

With the development of information technology, the importance of a display device, which is a connection medium between a user and information, has been highlighted. For example, the use of display devices such as liquid crystal display (LCD) devices, organic light emitting display (OLED) devices, plasma display panel (PDP) devices, quantum dot display devices or the like is increasing.

Among methods of manufacturing a display device, a method of manufacturing a display device by cutting a mother substrate, on which a plurality of display cells are formed, may be used. In other words, a display device may be manufactured by cutting the mother substrate along the plurality of display cells.

The above information disclosed in this Background section is only for enhancement of understanding of the background of the invention and therefore it may contain information that does not form the prior art.

### SUMMARY

Aspects of some embodiments are directed to a method of manufacturing a display device with improved process efficiency and improved process reliability.

Aspects of some embodiments are directed to an electronic device including a display device manufactured using the method.

According to some embodiments of the present disclosure, there is provided a method of manufacturing a display device, the method including: forming a display panel on a first surface of a mother substrate including a cell area and a dummy area surrounding the cell area, the display panel overlapping the cell area; attaching a protection film overlapping the display panel to the first surface of the mother substrate; forming a first cutting line along an edge of the cell area on the mother substrate; forming a second cutting line overlapping the dummy area and having a length greater than the first cutting line in a thickness direction of the mother substrate on the mother substrate; reducing a thickness of the mother substrate by spraying an etchant toward a second surface opposite to the first surface of the mother substrate; and removing the dummy area of the mother substrate by spraying the etchant toward the second surface of the mother substrate.

In some embodiments, in the removing the dummy area of the mother substrate, the thickness of the mother substrate is reduced by the etchant.

In some embodiments, the second cutting line contacts the etchant before the first cutting line.

In some embodiments, the removing the dummy area of the mother substrate includes separating the mother substrate into intermediate substrates along the second cutting line by spraying the etchant toward the second surface of the mother substrate.

In some embodiments, substrates are formed by removing the dummy area of the mother substrate, and a portion of a side surface of each of the substrates includes a curved surface.

In some embodiments, the mother substrate includes a first side extending in a first direction and a second side contacting the first side and extending in a second direction crossing the first direction, a length of the first side is greater than a length of the second side, and the second cutting line extends in the second direction.

In some embodiments, each of the first cutting line and the second cutting line extends from the first surface of the mother substrate toward the second surface of the mother substrate.

In some embodiments, each of the first cutting line and the second cutting line is formed by irradiating a laser to the mother substrate.

In some embodiments, the laser is irradiated to the second surface of the mother substrate.

In some embodiments, the protection film includes an acid-resistant film.

In some embodiments, the method further includes: forming a polarization layer on the display panel after the removing the dummy area of the mother substrate.

According to some embodiments of the present disclosure, there is provided a method of manufacturing a display device, the method including: forming a display panel on a first surface of a mother substrate including a cell area and a dummy area surrounding the cell area, the display panel overlapping the cell area; attaching a protection film overlapping the display panel to the first surface of the mother substrate; forming a first cutting line along an edge of the cell area on the mother substrate; forming a second cutting line overlapping the dummy area and having a length greater than the first cutting line in a thickness direction of the mother substrate on the mother substrate; reducing a thickness of the mother substrate by spraying an etchant toward a second surface opposite to the first surface of the mother substrate; separating the mother substrate into intermediate substrates along the second cutting line by spraying the etchant toward the second surface of the mother substrate; and separating each of the intermediate substrates into substrates along the first cutting line by spraying the etchant.

In some embodiments, in the separating the mother substrate into the intermediate substrates along the second cutting line, the thickness of the mother substrate is reduced by the etchant.

In some embodiments, in the separating each of the intermediate substrates into the substrates along the first cutting line, a thickness of each of the intermediate substrates is reduced by the etchant.

In some embodiments, the second cutting line contacts the etchant before the first cutting line.

In some embodiments, a portion of a side surface of each of the substrates includes a curved surface.

In some embodiments, the mother substrate includes a first side extending in a first direction and a second side contacting the first side and extending in a second direction intersecting the first direction, a length of the first side is greater than a length of the second side, and the second cutting line extends in the second direction.

In some embodiments, each of the first cutting line and the second cutting line extends from the first surface of the mother substrate toward the second surface of the mother substrate.

In some embodiments, each of the first cutting line and the second cutting line is formed by irradiating a laser to the mother substrate.

In some embodiments, the protection film includes an acid-resistant film.

According to some embodiments of the present disclosure, there is provided an electronic device including: a display device manufactured using the method described above; and a power supply configured to provide power to the display device.

Compared to the mother substrate, each of the intermediate substrates may have a relatively small size and a relatively small weight. Accordingly, in the process of separating each of the intermediate substrates into the substrates, a problem of deformation of the intermediate substrates may be prevented or the likelihood thereof may be substantially reduced. As a result, a problem of damage to a display panel due to penetration of the etchant may be prevented or the likelihood thereof may be substantially reduced, and the reliability of the process of separating the mother substrate into the substrates may be improved.

Other aspects, features, and characteristics that are not described above will be more clearly understood from the accompanying drawings, claims, and detailed description.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to some embodiments of the present disclosure.

FIG. 2 is a cross-sectional view of the display device taken along the line I-I′ of FIG. 1, according to some embodiments of the present disclosure.

FIG. 3 is a flowchart of a method of manufacturing a display device according to some embodiments of the present disclosure.

FIGS. 4 to 22 are views illustrating the method of manufacturing the display device of FIG. 3, according to some embodiments of the present disclosure.

FIG. 23 is a block diagram illustrating an electronic device according to some embodiments of the present disclosure.

FIG. 24 is a view illustrating an example in which the electronic device of FIG. 23 is implemented as a smart phone.

### DETAILED DESCRIPTION

Hereinafter, embodiments of the present disclosure will be described in detail with reference to the accompanying drawings. The same reference numerals are used for the same components in the drawings, and redundant descriptions of the same components will be omitted.

A person of ordinary skill in the art would appreciate, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the present disclosure, processes, elements, and techniques that are not considered necessary for those having ordinary skill in the art to have a complete understanding of the aspects and features of the present disclosure may not be described or may be only briefly described. In the drawings, the relative sizes of elements, layers, and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value. Furthermore, a specific quantity or range recited in this written description or the claims may also encompass the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

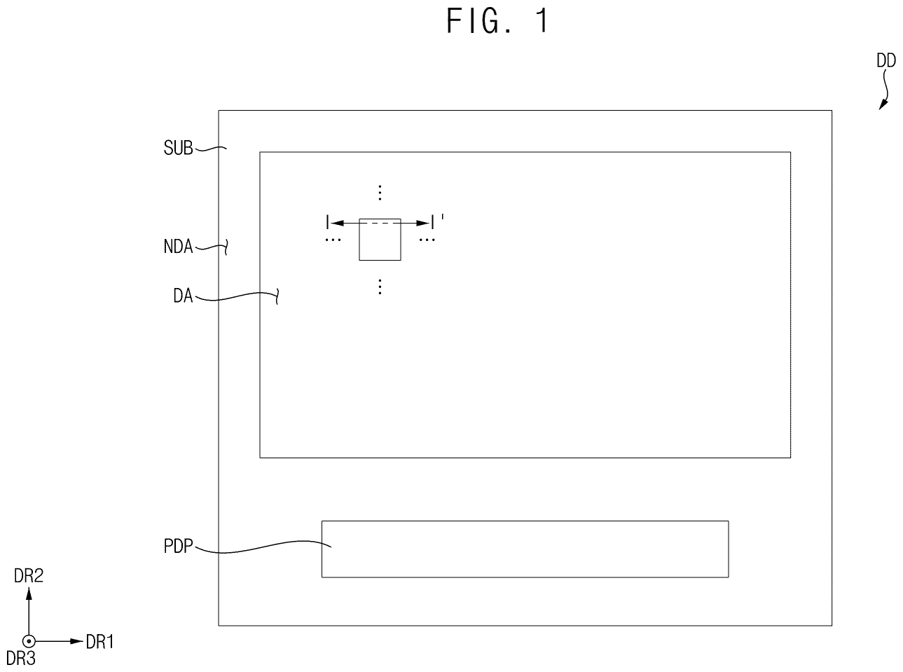

FIG. 1 is a plan view illustrating a display device according to some embodiments of the present disclosure.

In the present disclosure, a plane may be defined by a first direction DR1 and a second direction DR2 intersecting the first direction DR1. For example, the first direction DR1 and the second direction DR2 may be perpendicular to each other. A direction normal to the plane, that is, a thickness direction of a display device DD may be a third direction DR3. In other words, the third direction DR3 may be perpendicular to each of the first direction DR1 and the second direction DR2.

Referring to FIG. 1, the display device DD according to some embodiments of the present disclosure may include a substrate SUB and a pad portion PDP.

The substrate SUB may include a display area DA and a non-display area NDA. The display area DA may be defined as an area that displays an image by generating light or adjusting the transmittance of light provided from an external light source. A plurality of pixels PX may be disposed in the display area DA. Each of the pixels PX may generate light in response to a driving signal. For example, the pixels PX may be arranged in a matrix along the first direction DR1 and the second direction DR2.

In some embodiments, the display area DA may have a rectangular planar shape. For example, a length in the first direction DR1 of the display area DA may be greater than a length in the second direction DR2 of the display area DA. However, the planar shape of the display area DA is not limited thereto. For example, the display area DA may have any one of a square planar shape, a circular planar shape, and an oval planar shape.

The non-display area NDA may be defined as an area that does not display an image. The non-display area NDA may surround at least a portion of the display area DA in a plan view. For example, the non-display area NDA may entirely surround the display area DA in a plan view. A driving chip and a plurality of pads that provide the driving signal to the pixels PX may be disposed in the non-display area NDA.

The pad portion PDP may be disposed in the non-display area NDA on the substrate SUB. For example, the pad portion PDP may be spaced apart from the display area DA in the second direction DR2. The pad portion PDP may include the pads providing the driving signal to the pixels PX.

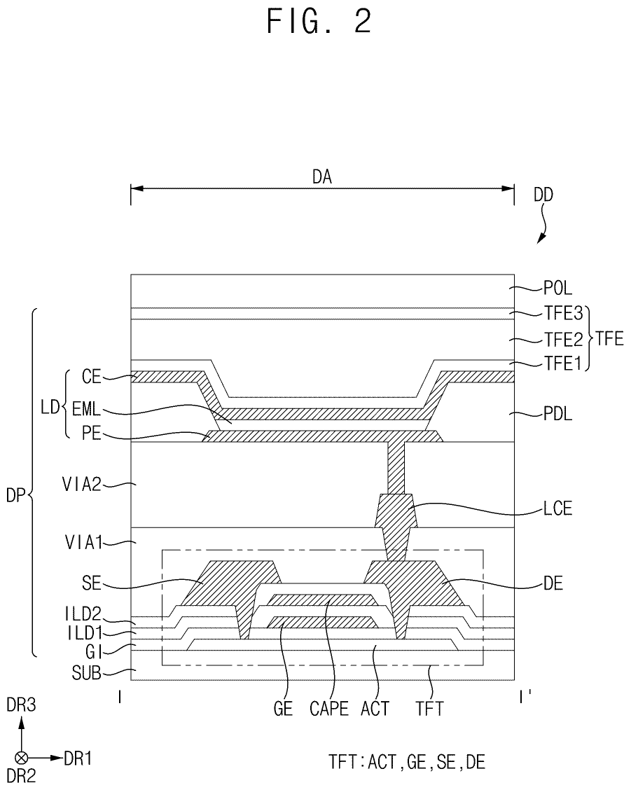

FIG. 2 is a cross-sectional view of the display device taken along the line I-I′ of FIG. 1, according to some embodiments of the present disclosure.

Referring to FIG. 2, the display device DD according to some embodiments of the present disclosure may include the substrate SUB, a display panel DP, and a polarization layer POL in the display area DA. The display panel DP may include a gate insulating layer GI, a first inter-layer insulating layer ILD1, a second inter-layer insulating layer ILD2, a thin film transistor TFT, a capacitor electrode CAPE, a first via-insulating layer VIA1, a connection electrode LCE, a second via-insulating layer VIA2, a pixel defining layer PDL, a light emitting element LD, and an encapsulation layer TFE.

The thin film transistor TFT may include an active pattern ACT, a gate electrode GE, a source electrode SE, and a drain electrode DE. The light emitting element LD may include a pixel electrode PE, a light emitting layer EML, and a common electrode CE. The encapsulation layer TFE may include a first inorganic encapsulation layer TFE1, an organic encapsulation layer TFE2, and a second inorganic encapsulation layer TFE3.

The substrate SUB may include a transparent material or an opaque material. For example, the substrate SUB may be formed of a transparent resin substrate. A polyimide substrate may be an example of the transparent resin substrate. In such examples, the polyimide substrate may include a first organic layer, a first barrier layer, a second organic layer, and/or the like. In some examples, the substrate SUB may include a quartz substrate, a synthetic quartz substrate, a calcium fluoride substrate, a fluorine-doped quartz substrate, a soda-lime glass substrate, a non-alkali glass substrate, or the like. These may be used alone or in combination with each other.

A buffer layer may be disposed on the substrate SUB. The buffer layer may prevent diffusion of metal atoms or impurities from the substrate SUB to an upper structure (e.g., the thin film transistor TFT, the light emitting element LD, etc.). In addition, the buffer layer may obtain the substantially uniform active pattern ACT by controlling a heat transfer rate during a crystallization process for forming the active pattern ACT. In addition, the buffer layer may serve to improve flatness of a surface of the substrate SUB when the surface of the substrate SUB is not uniform. For example, the buffer layer may include an inorganic insulating material. In some examples, the buffer layer may be omitted.

The active pattern ACT may be disposed on the substrate SUB. The active pattern ACT may include an oxide semiconductor, a silicon semiconductor, an organic semiconductor, and/or the like. For example, the oxide semiconductor may include at least one oxide selected from indium (In), gallium (Ga), tin (Sn), zirconium (Zr), vanadium (V), hafnium (Hf), cadmium (Cd), germanium (Ge), chromium (Cr), titanium (Ti), or zinc (Zn). The silicon semiconductor may include amorphous silicon, polycrystalline silicon, and/or the like. The active pattern ACT may include a source area, a drain area, and a channel area positioned between the source area and the drain area.

The gate insulating layer GI may be disposed on the substrate SUB. The gate insulating layer GI may cover the active pattern ACT on the substrate SUB and may be disposed along the profile of the active pattern ACT with a substantially uniform thickness. In some examples, the gate insulating layer GI may have a substantially flat upper surface without creating a step difference around the active pattern ACT. The gate insulating layer GI may include an inorganic insulating material. Examples of the inorganic insulating material that may be used as the gate insulating layer GI may include silicon oxide (SiOₓ), silicon nitride (SiNₓ), silicon oxynitride (SiOₓN_{y}), and/or the like. These may be used alone or in combination with each other. The gate insulating layer GI may electrically insulate the active pattern ACT from the gate electrode GE.

The gate electrode GE may be disposed on the gate insulating layer GI. The gate electrode GE may overlap the channel area of the active pattern ACT in a plan view. The gate electrode GE may include a metal, an alloy, a metal nitride, a conductive metal oxide, a transparent conductive material, and/or the like. Examples of material that may be used as the gate electrode GE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These may be used alone or in combination with each other.

The first inter-layer insulating layer ILD1 may be disposed on the gate insulating layer GI. The first inter-layer insulating layer ILD1 may cover the gate electrode GE on the gate insulating layer GI and may be disposed along the profile of the gate electrode GE with a substantially uniform thickness. In some examples, the first inter-layer insulating layer ILD1 may have a substantially flat upper surface without creating a step difference around the gate electrode GE. The first inter-layer insulating layer ILD1 may include an inorganic insulating material. Examples of the inorganic insulating material that may be used as the first inter-layer insulating layer ILD1 may include silicon oxide (SiOₓ), silicon nitride (SiNₓ), silicon oxynitride (SiOₓN_{y}), and/or the like. These may be used alone or in combination with each other. The first inter-layer insulating layer ILD1 may electrically insulate the gate electrode GE from the source electrode SE. In addition, the first inter-layer insulating layer ILD1 may electrically insulate the gate electrode GE from the drain electrode DE. In addition, the first inter-layer insulating layer ILD1 may electrically insulate the gate electrode GE from the capacitor electrode CAPE.

The capacitor electrode CAPE may be disposed on the first inter-layer insulating layer ILD1. The capacitor electrode CAPE may overlap the gate electrode GE in a plan view. The capacitor electrode CAPE may form a capacitor (e.g., a storage capacitor) with the gate electrode GE. For example, the capacitor electrode CAPE may include a metal, an alloy, a metal nitride, a conductive metal oxide, a transparent conductive material, or the like. They may be used alone or in combination with each other.

The second inter-layer insulating layer ILD2 may be disposed on the first inter-layer insulating layer ILD1. The second inter-layer insulating layer ILD2 may cover the capacitor electrode CAPE on the first inter-layer insulating layer ILD1 and may be disposed along the profile of the capacitor electrode CAPE with a substantially uniform thickness. In some examples, the second inter-layer insulating layer ILD2 may have a substantially flat upper surface without creating a step difference around the capacitor electrode CAPE. The second inter-layer insulating layer ILD2 may include an inorganic insulating material. Examples of the inorganic insulating material that may be used as the second inter-layer insulating layer ILD2 may include silicon oxide (SiOₓ), silicon nitride (SiNₓ), silicon oxynitride (SiOₓN_{y}), and/or the like. These may be used alone or in combination with each other. The second inter-layer insulating layer ILD2 may electrically insulate the capacitor electrode CAPE from the source electrode SE. In addition, the second inter-layer insulating layer ILD2 may electrically insulate the capacitor electrode CAPE from the drain electrode DE.

The source electrode SE and the drain electrode DE may be disposed on the second inter-layer insulating layer ILD2. The source electrode SE may be connected to the source area of the active pattern ACT through a contact hole formed through the gate insulating layer GI, the first inter-layer insulating layer ILD1, and the second inter-layer insulating layer ILD2. The drain electrode DE may be connected to the drain area of the active pattern ACT through a contact hole formed through the gate insulating layer GI, the first inter-layer insulating layer ILD1, and the second inter-layer insulating layer ILD2. For example, each of the source electrode SE and the drain electrode DE may include a metal, an alloy, a metal nitride, a conductive metal oxide, a transparent conductive material, and/or the like. These may be used alone or in combination with each other.

The first via-insulating layer VIA1 may be disposed on the second inter-layer insulating layer ILD2. For example, the first via-insulating layer VIA1 may be disposed on the second inter-layer insulating layer ILD2 with a relatively thick thickness and may cover the source electrode SE and the drain electrode DE. In such examples, the first via-insulating layer VIA1 may have a substantially flat upper surface. The first via-insulating layer VIA1 may include an organic insulating material. Examples of the organic insulating material that may be used as the first via-insulating layer VIA1 may include a photoresist, a polyacryl-based resin, a polyimide-based resin, a polyamide-based resin, a siloxane-based resin, an acryl-based resin, an epoxy-based resin, or the like. These may be used alone or in combination with each other.

The connection electrode LCE may be disposed on the first via-insulating layer VIA1. The connection electrode LCE may be connected to the drain electrode DE through a contact hole formed through the first via-insulating layer VIA1. For example, the connection electrode LCE may include a metal, an alloy, a metal nitride, a conductive metal oxide, a transparent conductive material, or the like. They may be used alone or in combination with each other.

The second via-insulating layer VIA2 may be disposed on the first via-insulating layer VIA1. For example, the second via-insulating layer VIA2 may be disposed on the first via-insulating layer VIA1 with a relatively thick thickness and may cover the connection electrode LCE. In such examples, the second via-insulating layer VIA2 may have a substantially flat upper surface. The second via-insulating layer VIA2 may include an organic insulating material. Examples of the organic insulating material that may be used as the second via-insulating layer VIA2 may include a photoresist, a polyacryl-based resin, a polyimide-based resin, a polyamide-based resin, a siloxane-based resin, an acryl-based resin, an epoxy-based resin, or the like. These may be used alone or in combination with each other.

The pixel electrode PE may be disposed on the second via-insulating layer VIA2. The pixel electrode PE may be connected to the connection electrode LCE through a contact hole formed through the second via-insulating layer VIA2. As a result, the pixel electrode PE may be electrically connected to the thin film transistor TFT through the connection electrode LCE. For example, the pixel electrode PE may include a metal, an alloy, a metal nitride, a conductive metal oxide, a transparent conductive material, or the like. These may be used alone or in combination with each other. For example, the pixel electrode PE may serve as an anode electrode.

The pixel defining layer PDL may be disposed on the second via-insulating layer VIA2. The pixel defining layer PDL may cover an edge of the pixel electrode PE and may have an opening exposing an upper surface of the pixel electrode PE. For example, the pixel defining layer PDL may include an organic insulating material or an inorganic insulating material. In some embodiments, the pixel defining layer PDL may include an organic insulating material. Examples of the organic insulating material that may be used as the pixel defining layer PDL may include a photoresist, a polyacryl-based resin, a polyimide-based resin, a polyamide-based resin, a siloxane-based resin, an acryl-based resin, an epoxy-based resin, or the like. These may be used alone or in combination with each other.

The light emitting layer EML may be disposed on the pixel electrode PE. The light emitting layer EML may be disposed on the upper surface of the pixel electrode PE exposed by the pixel defining layer PDL. The light emitting layer EML may emit light having a specific color (e.g., red, green, and/or blue). For example, the light emitting layer EML may include one or both of an organic light emitting material and a quantum dot. In some embodiments, the light emitting layer EML may have a single-layer structure including one light emitting layer. However, the present disclosure is not limited thereto, and the light emitting layer EML may have a tandem structure including a plurality of light emitting layers.

The common electrode CE may be disposed on the pixel defining layer PDL and the light emitting layer EML. The common electrode CE may be disposed along the profiles of the pixel defining layer PDL and the light emitting layer EML with a substantially uniform thickness. For example, the common electrode CE may include a metal, an alloy, a metal nitride, a conductive metal oxide, a transparent conductive material, or the like. These may be used alone or in combination with each other. For example, the common electrode CE may serve as a cathode electrode.

The encapsulation layer TFE may be disposed on the common electrode CE. The encapsulation layer TFE may prevent the penetration of impurities, moisture, or the like. from penetrating into the light emitting element LD from the outside. The encapsulation layer TFE may include at least one inorganic encapsulation layer and at least one organic encapsulation layer. In some embodiments, the encapsulation layer TFE may include the first inorganic encapsulation layer TFE1, the organic encapsulation layer TFE2, and the second inorganic encapsulation layer TFE3.

The first inorganic encapsulation layer TFE1 may be disposed on the common electrode CE. The first inorganic encapsulation layer TFE1 may cover the common electrode CE and may be disposed along the profile of the common electrode CE with a uniform thickness. The first inorganic encapsulation layer TFE1 may prevent or substantially reduce the likelihood of the light emitting element LD from being deteriorated due to penetration of impurities, moisture, or the like. In addition, the first inorganic encapsulation layer TFE1 may protect the light emitting element LD from an external impact. For example, the first inorganic encapsulation layer TFE1 may include a flexible inorganic insulating material.

The organic encapsulation layer TFE2 may be disposed on the first inorganic encapsulation layer TFE1. The organic encapsulation layer TFE2 may compensate for a step difference of the first inorganic encapsulation layer TFE1. Accordingly, the organic encapsulation layer TFE2 may have a substantially flat upper surface. The organic encapsulation layer TFE2 may protect the light emitting element LD from an external impact together with the first inorganic encapsulation layer TFE1. For example, the organic encapsulation layer TFE2 may include a flexible organic material.

The second inorganic encapsulation layer TFE3 may be disposed on the organic encapsulation layer TFE2. The first and second inorganic encapsulation layers TFE1 and TFE3 may prevent the light emitting element LD from being deteriorated due to penetration of impurities, moisture, or the like, or substantially reduce the likelihood of such damage, together with the first inorganic encapsulation layer TFE1. In addition, the second inorganic encapsulation layer TFE3 together with the first inorganic encapsulation layer TFE1 and the organic encapsulation layer TFE2 may protect the light emitting element LD from an external impact. For example, the second inorganic encapsulation layer TFE3 may include a flexible inorganic insulating material.

In some examples, the encapsulation layer TFE may have a five-layer structure with three inorganic encapsulation layers and two organic encapsulation layers alternately stacked with each other, or the encapsulation layer TFE may have a seven-layer structure with four inorganic encapsulation layers and three organic encapsulation layers alternately stacked with each other.

The polarization layer POL may be disposed on the encapsulation layer TFE. The polarization layer POL may polarize the external light. In other words, the polarization layer POL may reduce an external light reflection of the display device DD. As the external light reflection is reduced, the visibility of the display device DD may be improved (e.g., increased). In some examples, the polarization layer POL may be omitted.

Although the display device DD of the present disclosure is described by limiting the organic light emitting display (“OLED”) device, the configuration of the present disclosure is not limited thereto. In some other embodiments, the display device DD may include a liquid crystal display (“LCD”) device, a field emission display (“FED”) device, a plasma display panel (“PDP”) device, an electrophoretic image display (“EPD”) device, an inorganic light emitting display (“ILED”) device, or a quantum dot display device.

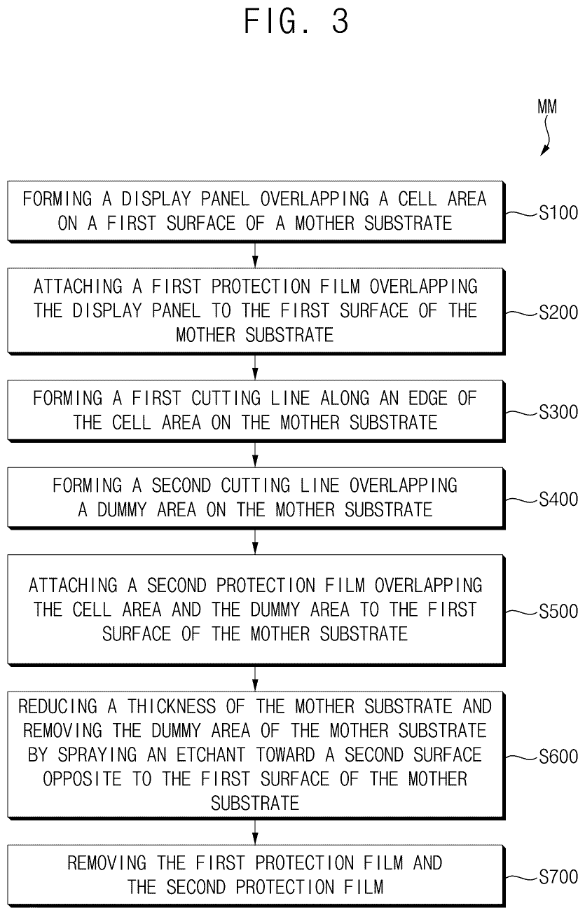

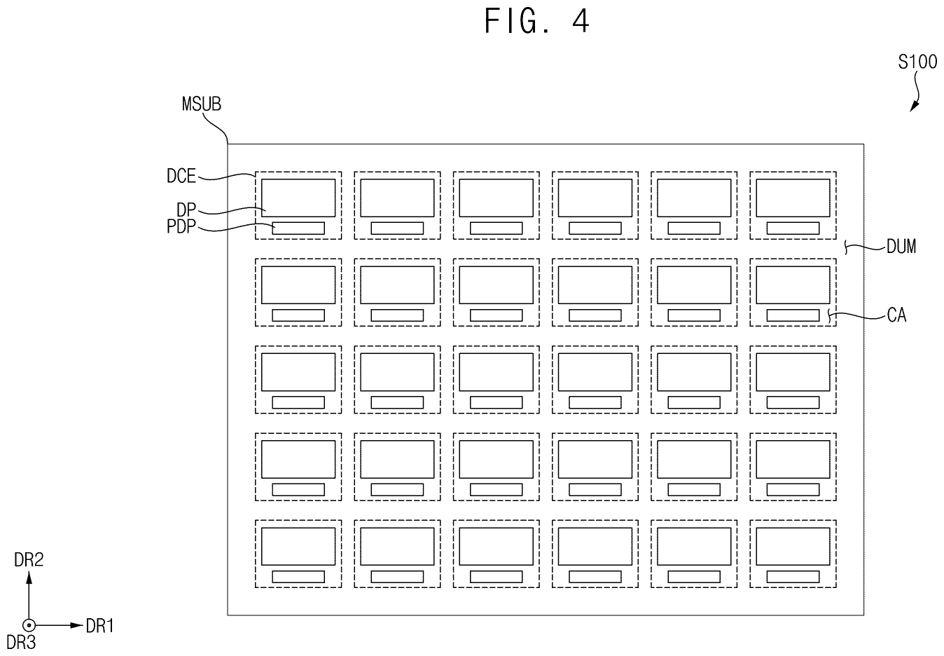

FIG. 3 is a flowchart of a method of manufacturing a display device according to some embodiments of the present disclosure. FIGS. 4 to 22 are views illustrating the method of manufacturing the display device of FIG. 3, according to some embodiments of the present disclosure.

Referring to FIG. 3, a method MM of manufacturing a display device according to some embodiments of the present disclosure may include forming a display panel overlapping a cell area on a first surface of a mother substrate (S100); attaching a first protection film overlapping the display panel to the first surface of the mother substrate (S200); forming a first cutting line along an edge of the cell area on the mother substrate (S300); forming a second cutting line overlapping a dummy area on the mother substrate (S400); attaching a second protection film overlapping the cell area and the dummy area to the first surface of the mother substrate (S500); reducing a thickness of the mother substrate and removing the dummy area of the mother substrate by spraying an etchant toward a second surface, which is opposite to the first surface, of the mother substrate (S600); and removing the first protection film and the second protection film (S700).

Referring to FIG. 4, a display panel DP overlapping a cell area CA may be formed on a first surface of a mother substrate MSUB.

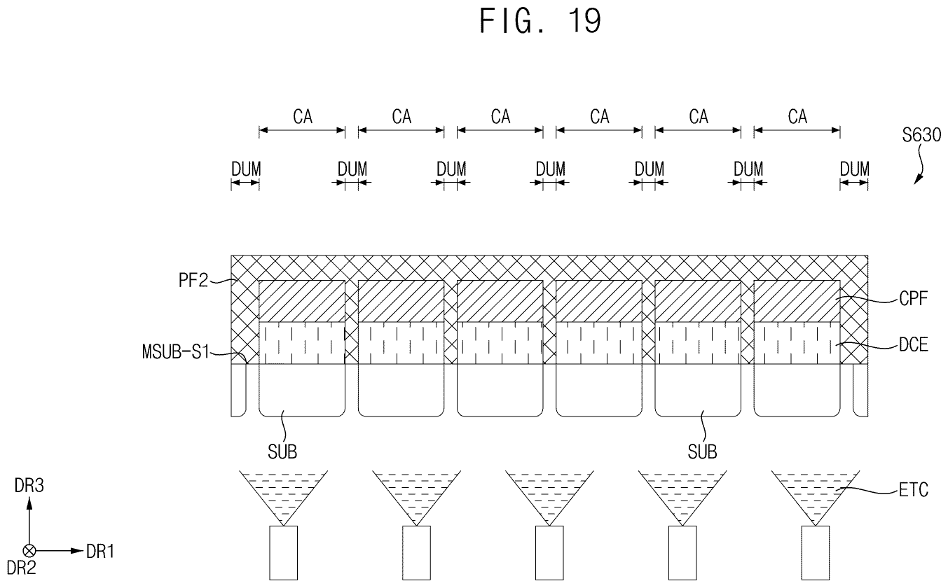

The mother substrate MSUB may include a transparent material or an opaque material. For example, the mother substrate MSUB may be formed of a transparent resin substrate. A polyimide substrate may be an example of the transparent resin substrate. In some examples, the mother substrate MSUB may include a quartz substrate, a synthetic quartz substrate, a calcium fluoride substrate, a fluorine-doped quartz substrate, a soda-lime glass substrate, a non-alkali glass substrate, or the like. These may be used alone or in combination with each other. The mother substrate MSUB may include a plurality of substrates (e.g., a substrate SUB of FIG. 19). The plurality of substrates may be formed by separating the mother substrate MSUB in a subsequent process.

The mother substrate MSUB may include the cell area CA and a dummy area DUM. The cell area CA may include the display area (DA; see, e.g., FIG. 1) and the non-display area (NDA; see, e.g., FIG. 1). The dummy area DUM may be located around the periphery of the cell area CA. In some embodiments, the dummy area DUM may surround the cell area CA. For example, the dummy area DUM may entirely surround the cell area CA. The dummy area DUM may be defined as an area that is removed in a subsequent process.

The display panel DP and a pad portion PDP may be formed on the first surface of the mother substrate MSUB to overlap the cell area CA. For example, the display panel DP may overlap the display area, and the pad portion PDP may overlap the non-display area (e.g., in a plan view).

The display panel DP may include the gate insulating layer GI, the first inter-layer insulating layer ILD1, the second inter-layer insulating layer ILD2, the thin film transistor TFT, the capacitor electrode CAPE, the first via-insulating layer VIA1, the connection electrode LCE, the second via-insulating layer VIA2, the pixel defining layer PDL, the light emitting element LD, and the encapsulation layer TFE, which are illustrated in FIG. 2. The pad portion PDP may be spaced apart from the display panel DP in the second direction DR2.

Accordingly, a display cell DCE including the display panel DP and the pad portion PDP may be formed. The display cell DCE may entirely overlap the cell area CA. When the dummy area DUM of the mother substrate MSUB is removed in a subsequent process, the display cell DCE may be used to manufacture one display device (e.g., the display device DD of FIG. 2).

As illustrated in FIG. 4, the display cells DCE may be arranged repeatedly along the first direction DR1 and the second direction DR2. For example, six display cells DCE may be repeatedly arranged along a row direction (or the first direction DR1). In other words, in each of first to fifth rows, six display cells DCE may be arranged in a line along the first direction DR1. In addition, five display cells DCE may be repeatedly arranged along a column direction (or the second direction DR2). In other words, in each of first to sixth columns, five display cells DCE may be arranged in a line along the second direction DR2. However, the arrangement of the display cells DCE is not limited thereto.

As illustrated in FIG. 4, thirty display cells DCE may be formed on the first surface of the mother substrate MSUB. However, the number of display cells DCE is not limited thereto. For example, less than thirty display cells DCE or more than thirty display cells DCE may be formed on the first surface of the mother substrate MSUB.

As illustrated in FIG. 4, the mother substrate MSUB may have a rectangular planar shape. In some embodiments, the mother substrate MSUB may include a first side extending in the first direction DR1 and a second side extending in the second direction DR2 contacting the first side. Here, the length of the first side may be greater than the length of the second side. In other words, the mother substrate MSUB may have a rectangular planar shape with the first side as a long side and the second side as a short side. However, the planar shape of the mother substrate MSUB is not limited thereto.

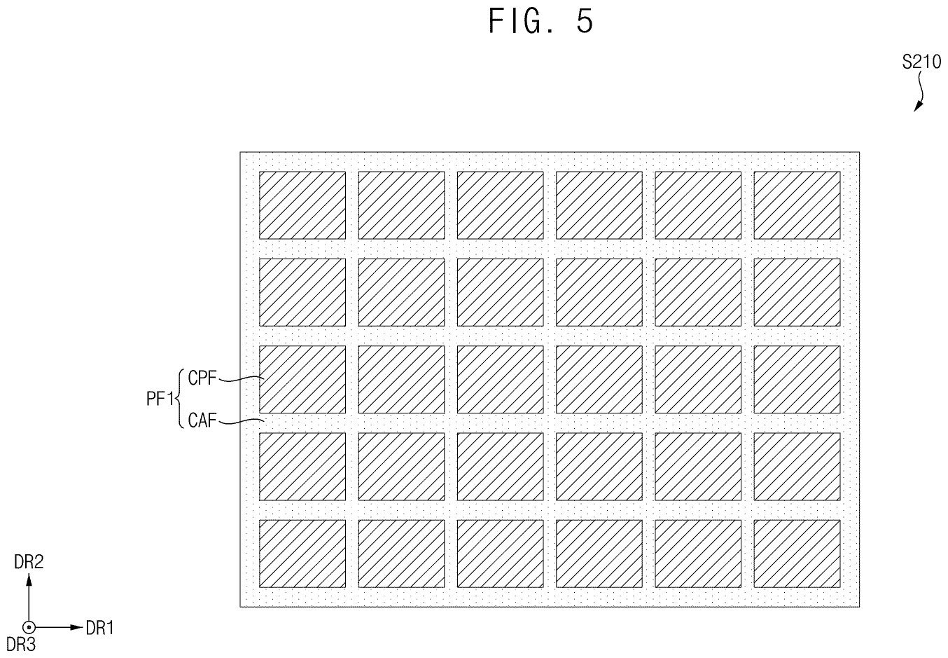

Referring to FIGS. 5, 6, 7, 8, 9, and 10, a first protection film PF1 overlapping the display panel DP may be attached to the first surface MSUB-S1 of the mother substrate MSUB (S200). The attaching the first protection film PF1 to the first surface MSUB-S1 of the mother substrate MSUB (S200) may include providing the first protection film PF1 (S210), attaching the first protection film PF1 to overlap the display panel DP (S220), and removing a carrier film CAF (S230).

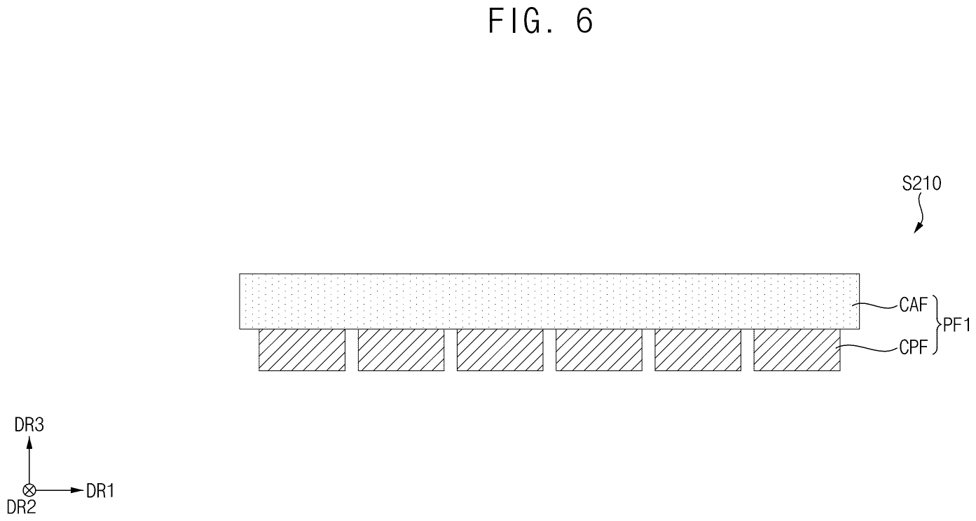

As illustrated in FIGS. 5 and 6, the first protection film PF1 including the carrier film CAF and cell protection films CPF may be provided (S210). The cell protection films CPF may be disposed on one surface of the carrier film CAF. The cell protection films CPF may be spaced apart from each other. For example, each of the cell protection films CPF may have a shape corresponding to a shape of the display cell DCE.

A shape in which the cell protection films CPF are arranged on the carrier film CAF may correspond to a shape in which the display cells DCE are arranged on the mother substrate MSUB. That is, a distance between the cell protection films CPF on the carrier film CAF may be the same as a distance between the display cells DCE on the mother substrate MSUB. For example, when thirty display cells DCE are formed on the mother substrate MSUB, thirty cell protection films CPF may be disposed on the carrier film CAF.

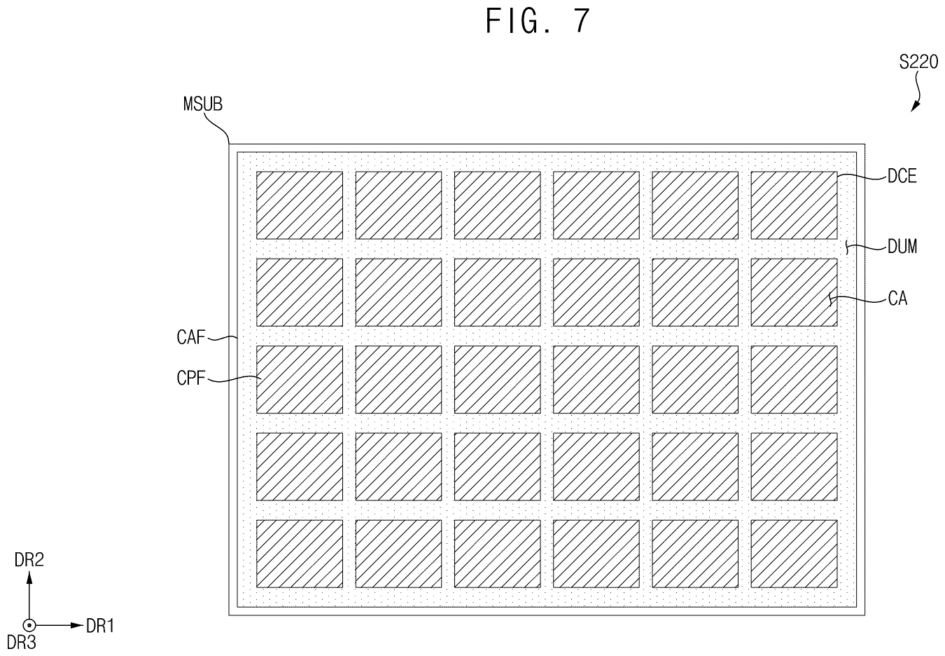

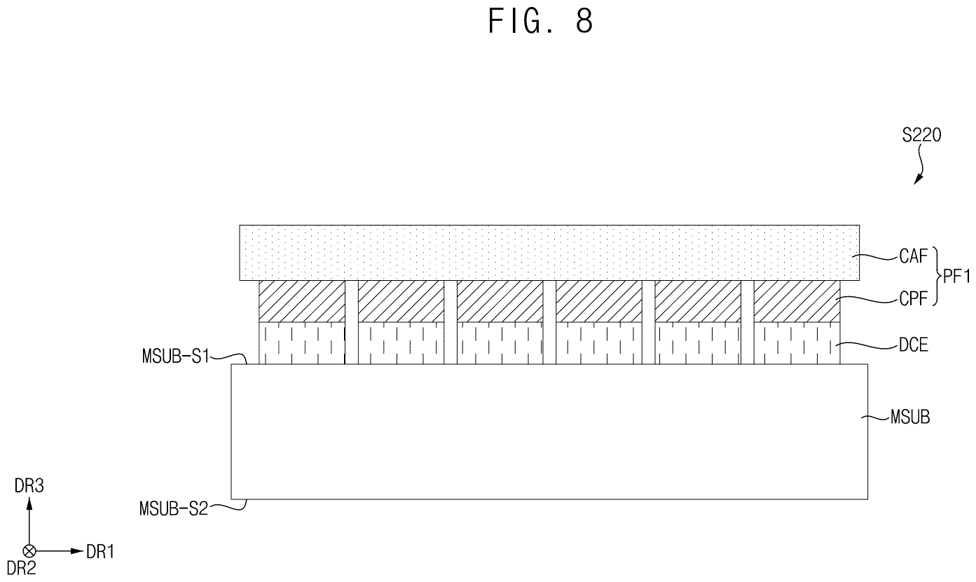

As illustrated in FIGS. 7 and 8, the first protection film PF1 may be attached to the first surface MSUB-S1 of the mother substrate MSUB so as to overlap the display panel DP (S220). For example, the first protection film PF1 may be attached to the first surface MSUB-S1 of the mother substrate MSUB so that each of the cell protection films CPF overlaps the display panel DP.

For example, each of the cell protection films CPF may entirely overlap the display cell DCE. In other words, each of the cell protection films CPF may entirely overlap the display panel DP and the pad portion PDP. In such examples, each of the cell protection films CPF may cover the display panel DP and the pad portion PDP. However, the present disclosure is not limited thereto. In another example, each of the cell protection films CPF may entirely overlap the display panel DP and not overlap the pad portion PDP. In such examples, each of the cell protection films CPF may cover the display panel DP and expose the pad portion PDP.

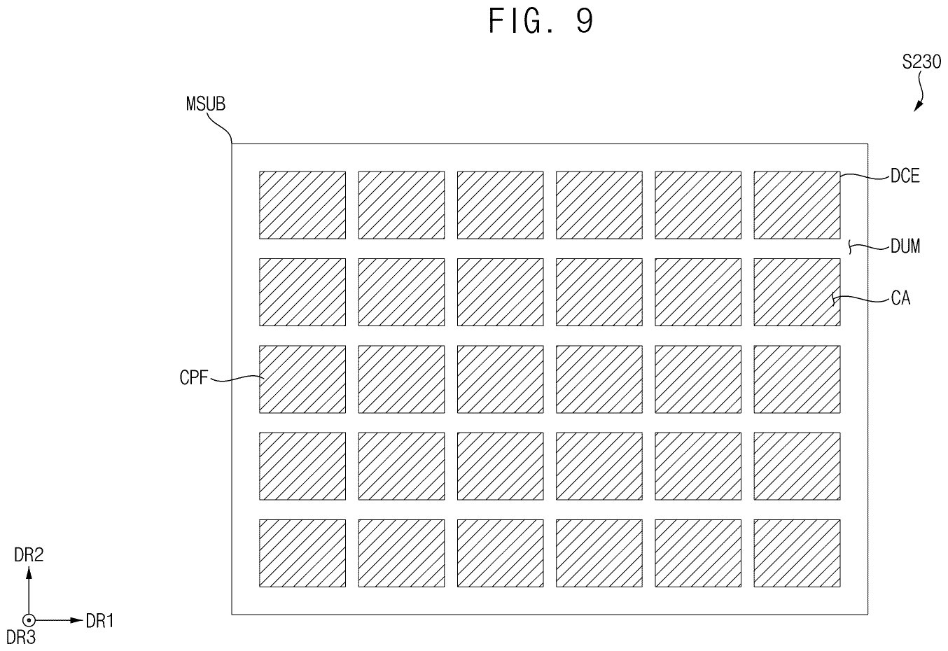

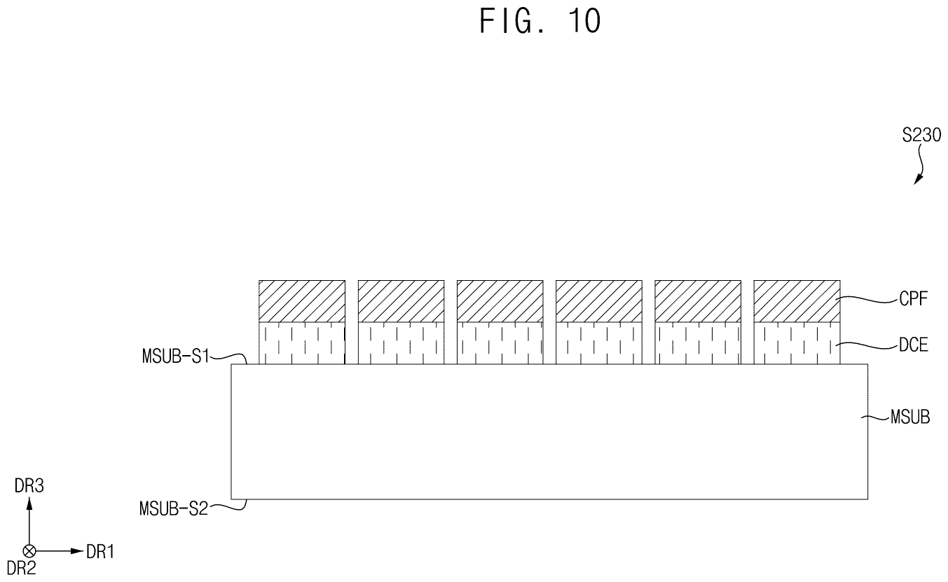

As illustrated in FIGS. 9 and 10, the carrier film CAF may be removed (S230).

After the carrier film CAF is aligned with the mother substrate MSUB and each of the cell protection films CPF is attached to the display cell DCE, the carrier film CAF may be removed. In other words, the cell protection films CPF may remain on the display cell DCE, and only the carrier film CAF may be removed.

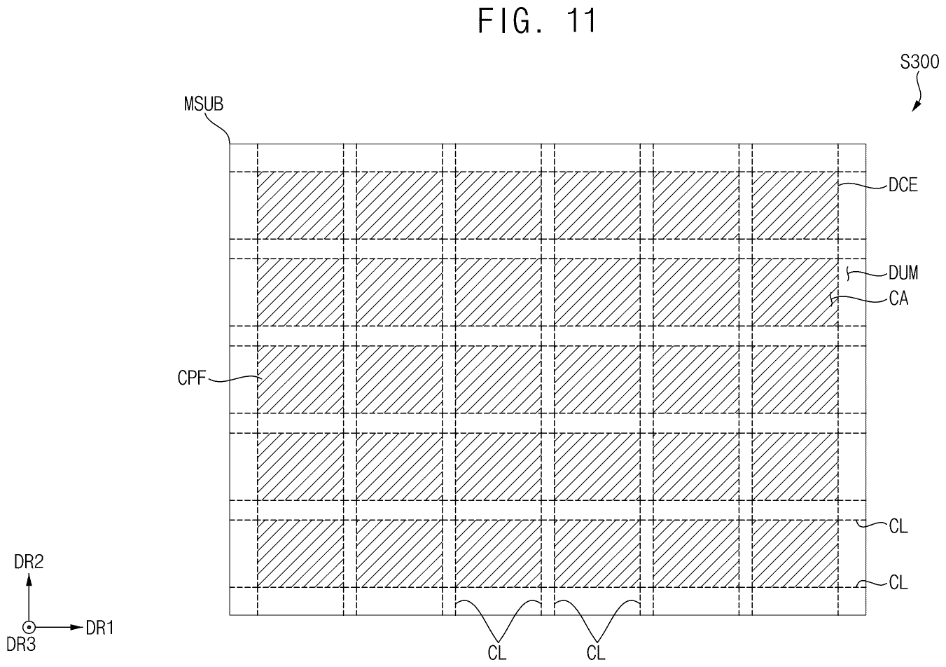

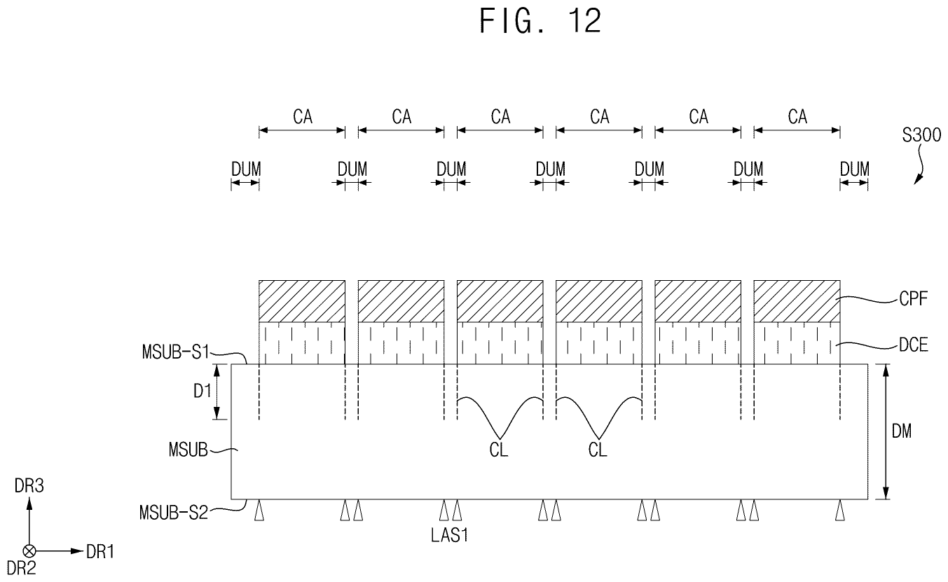

Referring to FIGS. 11 and 12, a first cutting line CL may be formed on the mother substrate MSUB (S300).

As illustrated in FIG. 11, the first cutting line CL may be formed on the mother substrate MSUB along an edge of the cell area CA. In other words, the first cutting line CL may be formed on the mother substrate MSUB along a first side of the display cell DCE extending in the first direction DR1 and a second side of the display cell DCE extending in the second direction DR2. The first cutting line CL may extend in the first direction DR1 or the second direction DR2.

As illustrated in FIG. 12, the first cutting line CL may extend from the first surface MSUB-S1 of the mother substrate MSUB toward a second surface MSUB-S2 of the mother substrate MSUB. Here, the second surface MSUB-S2 of the mother substrate MSUB may be defined as a surface opposite to the first surface MSUB-S1 of the mother substrate MSUB on which the display cell DCE is disposed. In other words, the first cutting line CL may extend from the first surface MSUB-S1 of the mother substrate MSUB toward a thickness direction of the mother substrate MSUB.

The first cutting line CL may be formed by irradiating the mother substrate MSUB with a laser. In some embodiments, the first cutting line CL may be formed by irradiating a first laser LAS1 on the second surface MSUB-S2 of the mother substrate MSUB. However, the present disclosure is not limited thereto, and the first cutting line CL may be formed by irradiating the first laser LAS1 on the first surface MSUB-S1 of the mother substrate MSUB.

A depth (e.g., a length in the third direction DR3) of the first cutting line CL may be smaller than a thickness DM of the mother substrate MSUB. For example, the thickness DM of the mother substrate MSUB may be about 500 micrometers, and a first depth D1 of the first cutting line CL may be about 240 micrometers. However, the thickness DM of the mother substrate MSUB and the first depth D1 of the first cutting line CL are not limited thereto.

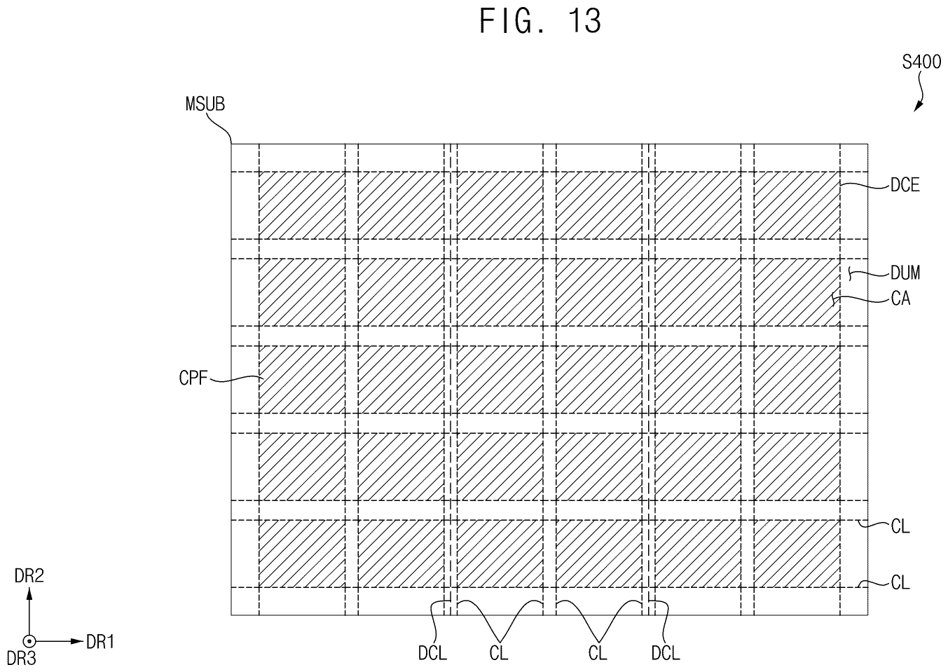

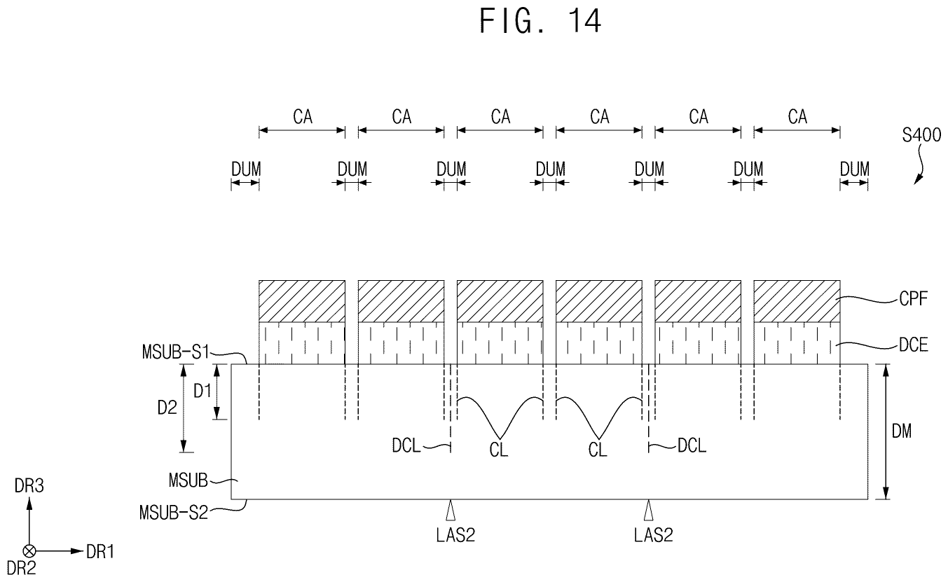

Referring to FIGS. 13 and 14, a second cutting line DCL may be formed on the mother substrate MSUB (S400).

As illustrated in FIG. 13, the second cutting line DCL may be formed in the dummy area DUM of the mother substrate MSUB. In some embodiments, when the mother substrate MSUB has a rectangular planar shape with the first side extending in the first direction DR1 as a long side and the second side extending in the second direction DR2 as a short side, the second cutting line DCL may extend in the second direction DR2. That is, the second cutting line DCL may extend perpendicular to a long side direction of the mother substrate MSUB. However, the present disclosure is not limited thereto, and the second cutting line DCL may extend parallel to the long side direction of the mother substrate MSUB.

For example, when five display cells DCE in each of the first to sixth columns are arranged in a line along the second direction DR2, the second cutting line DCL may be formed in the dummy area DUM between the second column and the third column and between the fourth column and the fifth column. However, the position where the second cutting line DCL is formed is not limited thereto. Depending on the size of the mother substrate MSUB and the shape of the display cells DCE arranged on the mother substrate MSUB, the position where the second cutting line DCL is formed may be changed.

For example, two second cutting lines DCL may be formed in the dummy area DUM of the mother substrate MSUB. However, the number of the second cutting lines DCL is not limited thereto. Depending on the size of the mother substrate MSUB and the shape of the display cells DCE arranged on the mother substrate MSUB, the number of the second cutting line DCL may be changed.

As illustrated in FIG. 14, the second cutting line DCL may extend from the first surface MSUB-S1 of the mother substrate MSUB toward the second surface MSUB-S2 of the mother substrate MSUB. In other words, the second cutting line DCL may extend from the first surface MSUB-S1 of the mother substrate MSUB toward the thickness direction of the mother substrate MSUB.

The second cutting line DCL may be formed by irradiating the mother substrate MSUB with a laser. In some embodiments, the second cutting line DCL may be formed by irradiating a second laser LAS2 on the second surface MSUB-S2 of the mother substrate MSUB. However, the present disclosure is not limited thereto, and the second cutting line DCL may be formed by irradiating the second laser LAS2 on the first surface MSUB-S1 of the mother substrate MSUB.

For example, the second laser LAS2 used to form the second cutting line DCL may be same as the first laser LAS1 used to form the first cutting line CL. However, the present disclosure is not limited thereto, and the second laser LAS2 may be different from the first laser LAS1.

A depth (e.g., a length in the third direction DR3) of the second cutting line DCL may be smaller than the thickness DM of the mother substrate MSUB. For example, the thickness DM of the mother substrate MSUB may be about 500 micrometers, and a second depth D2 of the second cutting line DCL may be about 300 micrometers. However, the thickness DM of the mother substrate MSUB and the second depth D2 of the second cutting line DCL are not limited thereto.

In exemplary embodiments, the second cutting line DCL may have a length greater than the first cutting line CL in the thickness direction of the mother substrate MSUB. In other words, the second depth D2 of the second cutting line DCL may be greater than the first depth D1 of the first cutting line CL. For example, the first depth D1 of the first cutting line CL may be about 240 micrometers, and the second depth D2 of the second cutting line DCL may be about 300 micrometers. However, the first depth D1 of the first cutting line CL and the second depth D2 of the second cutting line DCL are not limited thereto. The difference between the first depth D1 and the second depth D2 may vary depending on the process margin of forming a cutting line using a laser.

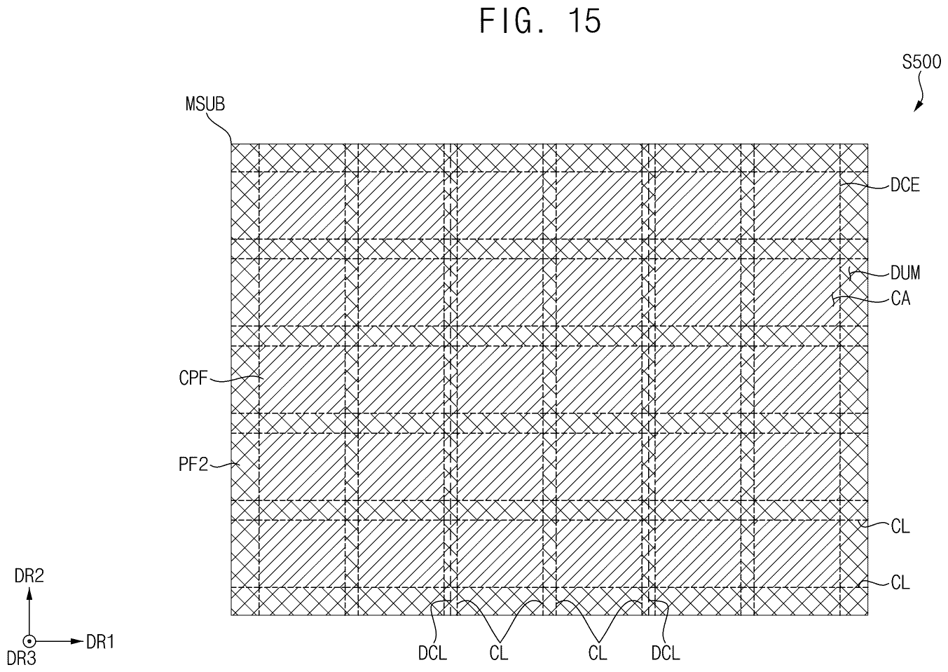

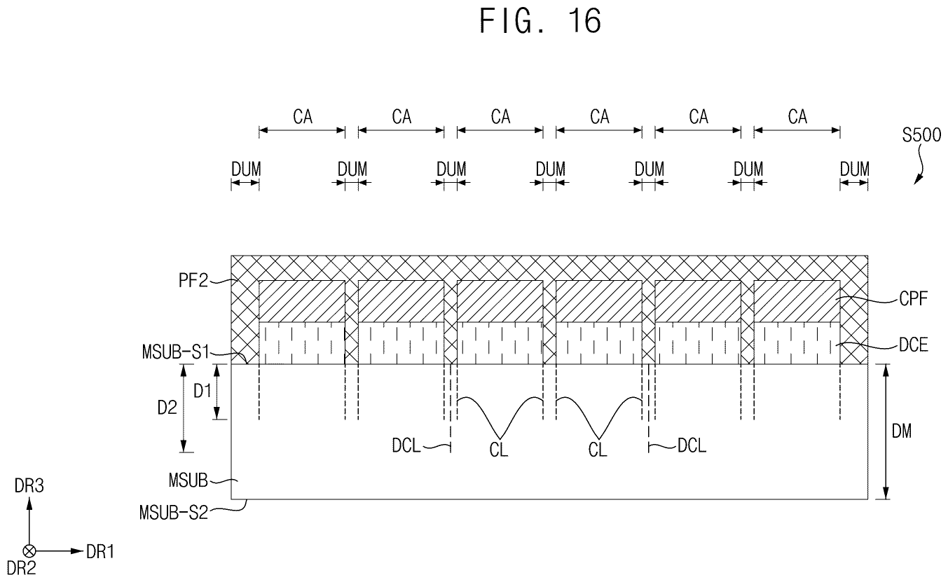

Referring to FIGS. 15 and 16, a second protection film PF2 may be attached to the first surface MSUB-S1 of the mother substrate MSUB (S500). The second protection film PF2 may overlap the cell area CA and the dummy area DUM.

The second protection film PF2 may overlap the display panel DP. For example, the second protection film PF2 may be disposed on the cell protection film CPF in the cell area CA, and may be disposed on the first surface MSUB-S1 of the mother substrate MSUB in the dummy area DUM. The second protection film PF2 may cover a side surface of the display cell DCE. In some embodiments, the second protection film PF2 may include an acid-resistant film. In such examples, the second protection film PF2 may protect the display cell DCE from an etchant.

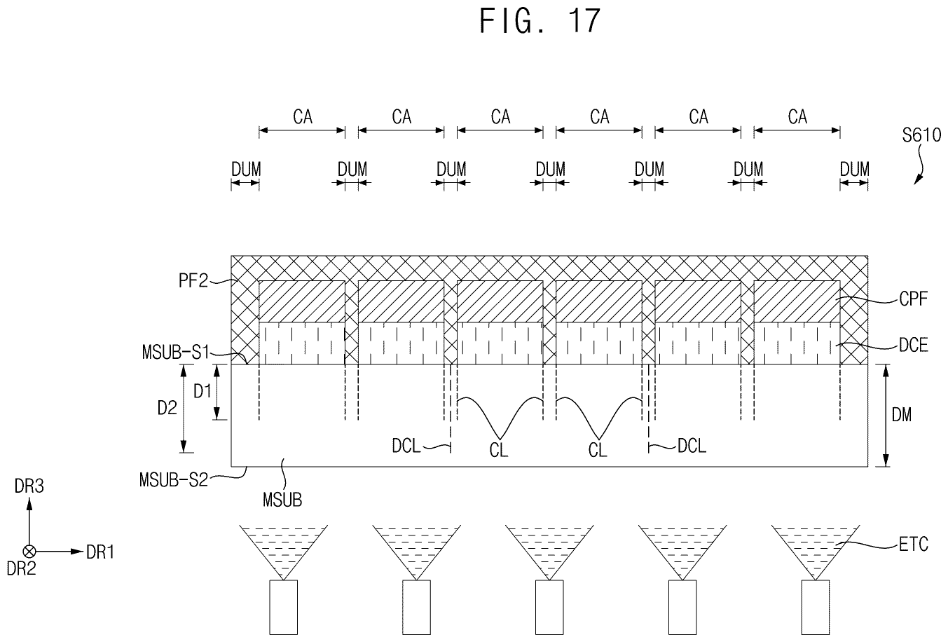

Referring to FIGS. 17, 18, and 19, by spraying an etchant ETC toward the second surface MSUB-S2 of the mother substrate MSUB, the thickness DM of the mother substrate MSUB may be reduced, and the dummy area DUM of the mother substrate MSUB may be removed (S600). For example, the spraying the etchant ETC toward the second surface MSUB-S2 of the mother substrate MSUB may include reducing the thickness DM of the mother substrate MSUB (S610), separating the mother substrate MSUB into a plurality of intermediate substrates ISUB along the second cutting line DCL (S620), and separating each of the intermediate substrates ISUB into a plurality of substrates SUB along the first cutting line CL (S630).

As illustrated in FIG. 17, by spraying the etchant ETC toward the second surface MSUB-S2 of the mother substrate MSUB, the thickness DM of the mother substrate MSUB may be reduced (S610). In such examples, because the mother substrate MSUB is etched without an etch mask, the second surface MSUB-S2 of the mother substrate MSUB may be uniformly etched as a whole, and the thickness DM of the mother substrate MSUB may be reduced.

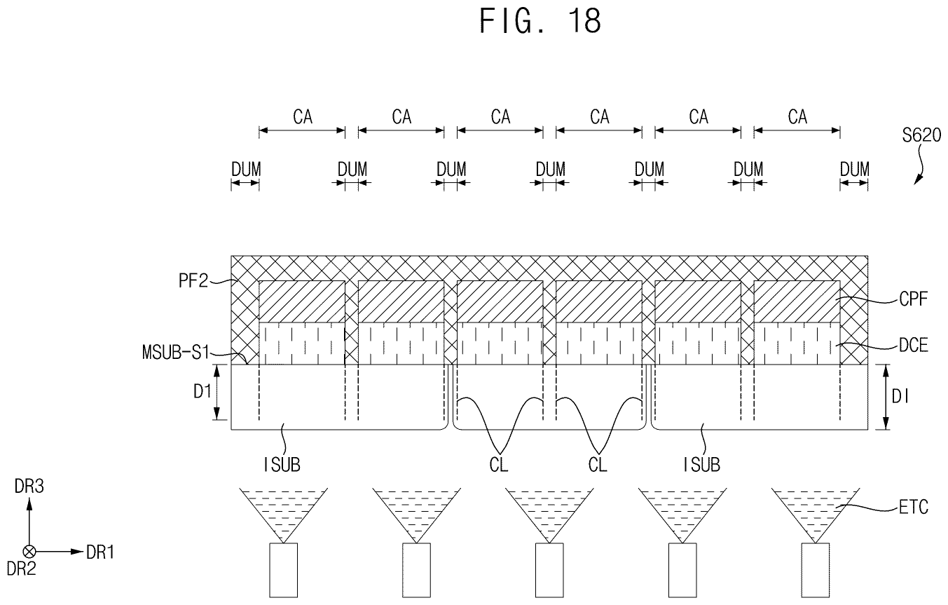

As illustrated in FIGS. 17 and 18, by spraying the etchant ETC toward the second surface MSUB-S2 of the mother substrate MSUB, the mother substrate MSUB may be separated into the intermediate substrates ISUB (S620).

As the thickness DM of the mother substrate MSUB continues to decrease by the etchant ETC, the etchant ETC may contact the second cutting line DCL. That is, because the second depth D2 of the second cutting line DCL is greater than the first depth D1 of the first cutting line CL, the second cutting line DCL may contact the etchant ETC before the first cutting line CL.

When the etchant ETC contacts the second cutting line DCL, a portion of the mother substrate MSUB adjacent to the second cutting line DCL may be etched relatively quickly as the etchant ETC penetrating into an inside of the mother substrate MSUB along the second cutting line DCL.

As the portion of the mother substrate MSUB adjacent to the second cutting line DCL is etched relatively quickly, the mother substrate MSUB may be separated into the intermediate substrates ISUB along the second cutting line DCL. The intermediate substrates ISUB may be spaced apart from each other in the first direction DR1 bounded by a position where the second cutting line DCL was formed. In some embodiments, a portion of a side surface of the intermediate substrate ISUB may include a curved surface. In other words, a lower surface of the intermediate substrate ISUB may include a dimple (or depression) caused by the etchant ETC.

In the process of separating the mother substrate MSUB into the intermediate substrates ISUB, the thickness DM of the mother substrate MSUB may continue to decrease. In other words, in the separating the mother substrate MSUB into the intermediate substrates ISUB along the second cutting line DCL, the thickness DM of the mother substrate MSUB may be reduced by the etchant ETC. That is, because the slimming process of the mother substrate MSUB and the separating process of the mother substrate MSUB may be performed concurrently (e.g., simultaneously), process efficiency may be improved (e.g., increased).

For example, two second cutting lines DCL may be formed in the dummy area DUM of the mother substrate MSUB, and the mother substrate MSUB may be separated along the two second cutting lines DCL. Accordingly, the mother substrate MSUB may be separated into three intermediate substrates ISUB. However, the number of the intermediate substrates ISUB formed is not limited thereto.

As illustrated in FIGS. 18 and 19, each of the intermediate substrates ISUB may be separated into the plurality of substrates SUB (S630).

As a thickness DI of the intermediate substrate ISUB continues to decrease by the etchant ETC, the etchant ETC may contact the first cutting line CL. When the etchant ETC contacts the first cutting line CL, a portion of the intermediate substrate ISUB adjacent to the first cutting line CL may be etched relatively quickly as the etchant ETC penetrating into an inside of the intermediate substrate ISUB along the first cutting line CL.

As the portion of the intermediate substrate ISUB adjacent to the first cutting line CL is etched relatively quickly, the intermediate substrate ISUB may be separated into the substrates SUB along the first cutting line CL. Accordingly, the substrates SUB overlapping the cell area CA may be formed, and a portion of the mother substrate MSUB overlapping the dummy area DUM may be removed. For example, the substrates SUB overlapping the cell area CA may be formed, and a portion of the intermediate substrate ISUB overlapping the dummy area DUM may be removed.

The substrates SUB may be spaced apart from each other in the first direction DR1 bounded by a position where the first cutting line CL was formed. In some embodiments, a portion of a side surface of the substrate SUB may include a curved surface. In other words, a lower surface of the substrate SUB may include a dimple (or depression) caused by the etchant ETC.

In the process of separating the intermediate substrate ISUB into the substrates SUB, the thickness DI of the intermediate substrate ISUB may continue to decrease. In other words, in the separating the intermediate substrate ISUB into the substrates SUB along the first cutting line CL, the thickness DI of the intermediate substrate ISUB may be reduced by the etchant ETC. That is, because the slimming process of the intermediate substrate ISUB and the separating process of the intermediate substrate ISUB may be performed concurrently (e.g., simultaneously), process efficiency may be improved.

As a size and a weight of the mother substrate MSUB becomes relatively large, in a conventional process of separating the mother substrate MSUB into the substrates SUB, a problem in which the mother substrate MSUB is deformed may occur. For example, a problem may occur in which a portion of the mother substrate MSUB is bent at a position where a cutting line is formed. In addition, the etchant ETC may penetrate into the portion of the mother substrate MSUB where deformation occurs, causing damage to the display cell DCE or the display panel DP.

The method MM of manufacturing the display device according to some embodiments of the present disclosure may include separating the mother substrate MSUB into the intermediate substrates ISUB along the second cutting line DCL formed in the dummy area DUM, prior to separating the mother substrate MSUB into the substrates SUB along the first cutting line CL formed along an edge of the cell area CA. By separating the mother substrate MSUB into the intermediate substrates ISUB, a size of each of the intermediate substrates ISUB may be smaller than a size of the mother substrate MSUB, and a weight of each of the intermediate substrates ISUB may be less than (e.g., relatively smaller than) a weight of the mother substrate MSUB.

That is, in the process of separating the intermediate substrate ISUB, which has a relatively small weight, into the substrates SUB, a problem of deformation of the intermediate substrate ISUB may be prevented or the likelihood thereof may be substantially reduced. For example, a problem of the intermediate substrate ISUB being bent at a position where the first cutting line CL is formed may be prevented or the likelihood thereof may be substantially reduced. Accordingly, a problem of damage to the display cell DCE or the display panel DP due to penetration of the etchant ETC may be prevented or the likelihood thereof may be substantially reduced, and the reliability of the process of separating the mother substrate MSUB into the substrates SUB may be improved (e.g., increased).

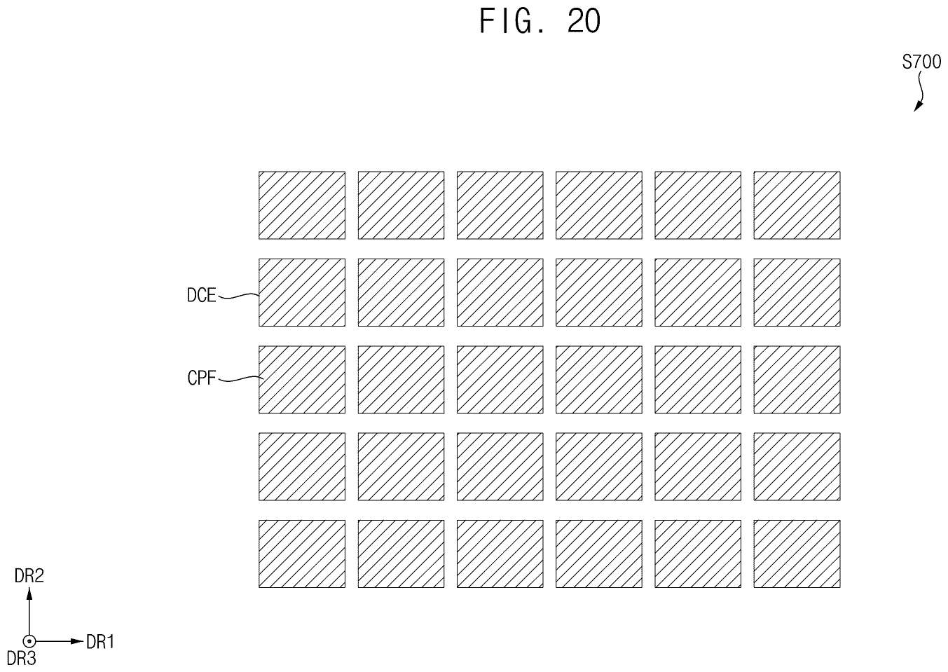

Referring to FIGS. 20, 21, and 22, the first protection film PF1 and the second protection film PF2 may be removed (S700). For example, after removing the second protection film PF2, the cell protection films CPF may be removed.

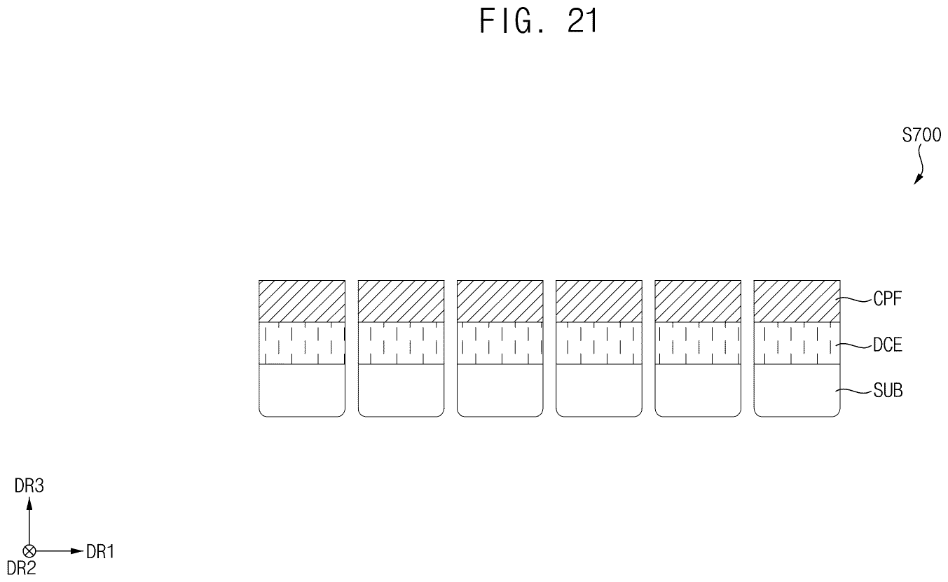

As illustrated in FIGS. 20 and 21, the second protection film PF2 covering a side surface of the display cell DCE and the cell protection film CPF may be removed. For example, the second protection film PF2 may be removed after the process of spraying the etchant ETC.

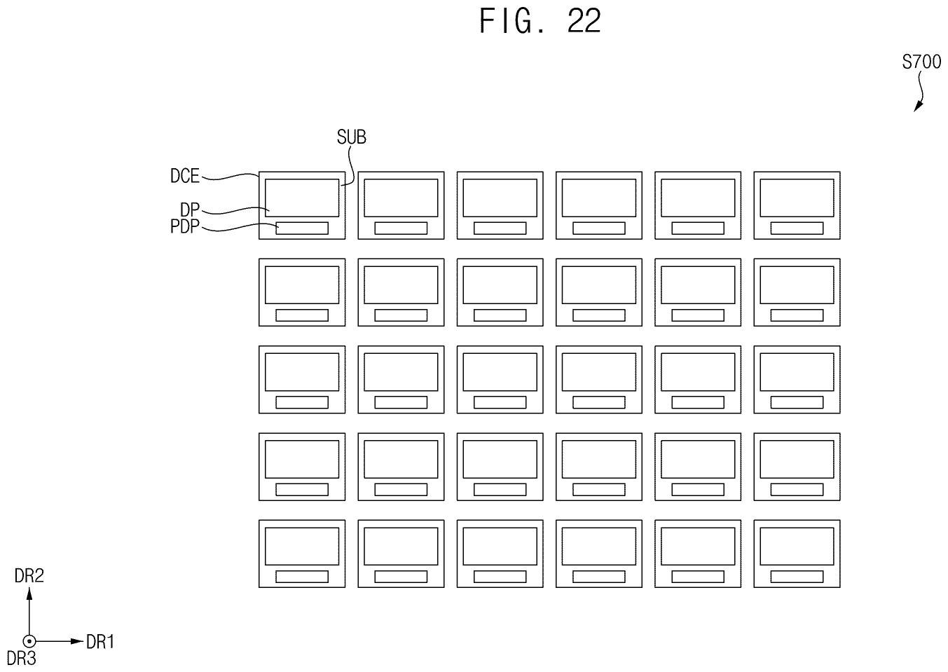

As illustrated in FIG. 22, the cell protection films CPF that respectively overlap the display cells DCE may be removed.

Each of the display cells DCE may be used to manufacture one display device. In some embodiments, after the cell protection films CPF are removed, a polarization layer (POL; see, e.g., FIG. 2) may be formed on the display panel DP. For example, after the cell protection films CPF are removed, the polarization layer may be formed on the encapsulation layer. Accordingly, the display device DD which is illustrated in FIG. 2 including the substrate SUB, the display panel DP, the pad portion PDP, and the polarization layer may be formed.

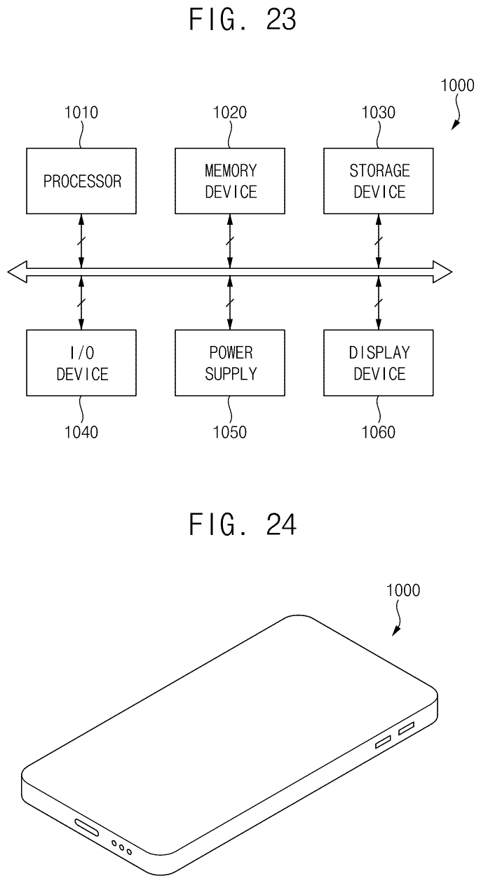

FIG. 23 is a block diagram illustrating an electronic device according to some embodiments of the present disclosure. FIG. 24 is a view illustrating an example in which the electronic device of FIG. 23 is implemented as a smart phone.

Referring to FIGS. 23 and 24, an electronic device 1000 may include a processor 1010, a memory device 1020, a storage device 1030, an input/output (I/O) device 1040, a power supply 1050, and a display device 1060. The display device 1060 may be the display device DD of FIG. 1. In addition, the electronic device 1000 may further include a plurality of ports for communicating with a video card, a sound card, a memory card, a universal serial bus (“USB”) device, other systems, and the like.

In an embodiment, as illustrated in FIG. 24, the electronic device 1000 may be implemented as a smart phone. However, the electronic device 1000 is not limited thereto. For example, the electronic device 1000 may be implemented as a smart pad, a smart watch, a tablet PC, a car navigation system, a computer monitor, a laptop, a head mounted display (“HMD”) device, and the like.

The processor 1010 may perform various computing functions. The processor 1010 may be a microprocessor, a central processing unit (“CPU”), an application processor (“AP”), and the like. The processor 1010 may be coupled to other components through an address bus, a control bus, a data bus, and the like. In an embodiment, the processor 1010 may be coupled to an extended bus such as a peripheral component interconnection (“PCI”) bus.

The memory device 1020 may store data for operations of the electronic device 1000. For example, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and the like and/or at least one volatile memory device such as a dynamic random access memory (“DRAM”) device, a static random access memory (“SRAM”) device, a mobile DRAM device, and the like.

The storage device 1030 may include a solid-state drive (“SSD”) device, a hard disk drive (“HDD”) device, a CD-ROM device, and the like. The I/O device 1040 may include an input device such as a keyboard, a keypad, a mouse device, a touch-pad, a touch-screen, and the like, and an output device such as a printer, a speaker, and the like. In some embodiments, the I/O device 1040 may include the display device 1060.

The power supply 1050 may provide power for operations of the electronic device 1000. In other words, the power supply 1050 may provide power to the display device 1060. The display device 1060 may be connected to other components through buses or other communication links.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined by the appended claims and equivalents thereof.

What is claimed is:

1. A method of manufacturing a display device, the method comprising:
forming a display panel on a first surface of a mother substrate comprising a cell area and a dummy area surrounding the cell area, the display panel overlapping the cell area;
attaching a protection film overlapping the display panel to the first surface of the mother substrate;
forming a first cutting line along an edge of the cell area on the mother substrate;
forming a second cutting line overlapping the dummy area and having a length greater than the first cutting line in a thickness direction of the mother substrate on the mother substrate;
reducing a thickness of the mother substrate by spraying an etchant toward a second surface opposite to the first surface of the mother substrate; and
removing the dummy area of the mother substrate by spraying the etchant toward the second surface of the mother substrate.

2. The method of claim 1, wherein in the removing the dummy area of the mother substrate, the thickness of the mother substrate is reduced by the etchant.

3. The method of claim 1, wherein the second cutting line contacts the etchant before the first cutting line.

4. The method of claim 1, wherein the removing the dummy area of the mother substrate comprises separating the mother substrate into intermediate substrates along the second cutting line by spraying the etchant toward the second surface of the mother substrate.

5. The method of claim 1, wherein substrates are formed by removing the dummy area of the mother substrate, and
wherein a portion of a side surface of each of the substrates comprises a curved surface.

6. The method of claim 1, wherein the mother substrate comprises a first side extending in a first direction and a second side contacting the first side and extending in a second direction crossing the first direction,
wherein a length of the first side is greater than a length of the second side, and
wherein the second cutting line extends in the second direction.

7. The method of claim 1, wherein each of the first cutting line and the second cutting line extends from the first surface of the mother substrate toward the second surface of the mother substrate.

8. The method of claim 7, wherein each of the first cutting line and the second cutting line is formed by irradiating a laser to the mother substrate.

9. The method of claim 8, wherein the laser is irradiated to the second surface of the mother substrate.

10. The method of claim 1, wherein the protection film comprises an acid-resistant film.

11. The method of claim 1, further comprising:
forming a polarization layer on the display panel after the removing the dummy area of the mother substrate.

12. A method of manufacturing a display device, the method comprising:
forming a display panel on a first surface of a mother substrate comprising a cell area and a dummy area surrounding the cell area, the display panel overlapping the cell area;
attaching a protection film overlapping the display panel to the first surface of the mother substrate;
forming a first cutting line along an edge of the cell area on the mother substrate;
forming a second cutting line overlapping the dummy area and having a length greater than the first cutting line in a thickness direction of the mother substrate on the mother substrate;
reducing a thickness of the mother substrate by spraying an etchant toward a second surface opposite to the first surface of the mother substrate;
separating the mother substrate into intermediate substrates along the second cutting line by spraying the etchant toward the second surface of the mother substrate; and
separating each of the intermediate substrates into substrates along the first cutting line by spraying the etchant.

13. The method of claim 12, wherein in the separating the mother substrate into the intermediate substrates along the second cutting line, the thickness of the mother substrate is reduced by the etchant.

14. The method of claim 13, wherein in the separating each of the intermediate substrates into the substrates along the first cutting line, a thickness of each of the intermediate substrates is reduced by the etchant.

15. The method of claim 12, wherein the second cutting line contacts the etchant before the first cutting line.

16. The method of claim 12, wherein a portion of a side surface of each of the substrates comprises a curved surface.

17. The method of claim 12, wherein the mother substrate comprises a first side extending in a first direction and a second side contacting the first side and extending in a second direction intersecting the first direction,
wherein a length of the first side is greater than a length of the second side, and
wherein the second cutting line extends in the second direction.

18. The method of claim 12, wherein each of the first cutting line and the second cutting line extends from the first surface of the mother substrate toward the second surface of the mother substrate.

19. The method of claim 18, wherein each of the first cutting line and the second cutting line is formed by irradiating a laser to the mother substrate.

20. The method of claim 12, wherein the protection film comprises an acid-resistant film.

21. An electronic device comprising:
a display device manufactured according to the method of claim 1; and
a power supply configured to provide power to the display device.
